(19) United States
(12) Patent Application Publication
(10) Pub. No.: US 2026/0215108 A1
(43) Pub. Date: Jul. 23, 2026

(54) DISPLAY PANEL

(71) Applicant: GIANTPLUS TECHNOLOGY CO., LTD., Miauli County (TW)

(72) Inventors: I-Ta JIANG, Miauli County (TW); Che-Yao WU, Miauli County (TW); Kai-Ju CHOU, Miauli County (TW)

(73) Assignee: GIANTPLUS TECHNOLOGY CO., LTD., Miauli County (TW)

(21) Appl. No.: 19/278,809

(22) Filed: Jul. 24, 2025

(30) Foreign Application Priority Data
Jan. 22, 2025 (TW) 114200869

(51) Int. Cl. H10K 59/131; H10K 59/60; H10K 59/80

(52) U.S. Cl. CPC H10K 59/131; H10K 59/60; H10K 59/873

(57) ABSTRACT

A display panel includes an array substrate, a sealant layer in a non-display area connecting to the array substrate, and an optical substrate, which includes a solar energy conversion layer in the non-display area, a first organic layer covering the solar energy conversion layer, an electrode conductive layer including a negative electrode conductive layer and a positive electrode conductive layer, a second organic layer on the electrode conductive layer, and a common electrode layer on the second organic layer connecting the sealant layer. An annular opening of the first organic layer corresponds to the sealant layer. The negative electrode conductive layer connects the solar energy conversion layer of a first border area, a second border area and a third border area exposed by the first organic layer. The positive electrode conductive layer connects the solar energy conversion layer of a fourth border area exposed by the first organic layer.

### CROSS REFERENCE TO RELATED PRESENT DISCLOSURE

This application claims the priority benefit of Taiwan Utility Model Patent Application Serial Number 114200869, filed on January 22, 2025, the full disclosure of which is incorporated herein by reference.

### TECHNICAL FIELD

The present disclosure relates to a display panel, in particular to a display panel having solar cells.

### RELATED ART

In order to meet the needs of life or work, it has become a social trend to carry electronic products with display panels. In addition to carrying a power bank to recharge electronic products, charging electronic products through solar energy is also one of the new charging methods.

Considering the reduction of the overall thickness of a display panel with solar cells, a display panel with a common conduction design can be used. To allow the conductive path of the solar cells to be directly transmitted from bus lines on the color filter layer side to a flexible circuit board on the color filter layer side, to effectively avoid the electrical attenuation of the solar cells during transmission, a double-sided bonding structure can be used. However, based on the consideration of both display function and photoelectric conversion function, a first organic layer located in the left and right frame areas of the display panel needs to be provided with through openings for wiring connection of the solar cells, and a common electrode layer on the color filter layer side needs to be provided with a second organic layer to isolate the solar cells. Therefore, a gap between the left and right frame areas of the display panel is larger than a gap between the upper and lower frame areas, resulting in uneven display effect (i.e., mura) of the existing display panel.

Therefore, how to provide a display panel that can solve the problem of uneven display is one of the problems to be solved in the field.

### SUMMARY

The embodiments of the present disclosure provide a display panel that can solve the problem of uneven display caused by the gap between the left and right frame areas being larger than the gap between the upper and lower frame areas in the existing display panel.

To achieve the above-mentioned purpose, the present disclosure provides a display panel, which having a display area and a non-display area surrounding the display area, wherein the non-display area includes a first border area and a second border area disposed opposite to each other along a first direction, and a third border area and a fourth border area disposed opposite to each other along a second direction, and the first direction is perpendicular to the second direction. The display panel includes an array substrate, a sealant layer and an optical substrate. The sealant layer is disposed on the array substrate and corresponds to the non-display area, and the sealant layer is electrically connected to the array substrate. The optical substrate is disposed on the sealant layer and includes a solar energy conversion layer, a first organic layer, an electrode conductive layer, a second organic layer and a common electrode layer. The solar energy conversion layer is disposed in the non-display area. The first organic layer is configured to cover the solar energy conversion layer and is provided with an annular opening, the annular opening is disposed corresponding to the sealant layer, and the annular opening exposes a portion of the solar energy conversion layer located in the non-display area. The electrode conductive layer is disposed on the first organic layer and includes a negative electrode conductive layer and a positive electrode conductive layer. The negative electrode conductive layer is electrically connected to the solar energy conversion layer located in the first border area, the second border area and the third border area and exposed by the first organic layer. The positive electrode conductive layer is electrically connected to the solar energy conversion layer located in the fourth border area and exposed by the first organic layer. The second organic layer is disposed on the electrode conductive layer. The common electrode layer is disposed on the second organic layer and is electrically connected to the sealant layer.

Based on the above content, the display panel of the embodiments of the present disclosure is designed by the annular opening in the first organic layer corresponding to the sealant layer, the electrical connection between the negative conductive layer and the solar energy conversion layer located in the first border area, the second border area and the third border area and exposed by the first organic layer, and the electrical connection between the positive conductive layer and the solar energy conversion layer located in the fourth border area and exposed by the first organic layer, so that the sealant layer of the display panel has the same/similar width and height in the first border area, the second border area, the third border area and the fourth border area. The second organic layer is configured to electrically isolate the solar energy conversion layer with photoelectric conversion capability from the common electrode layer, so that it can avoid affecting the electrical properties of the solar energy conversion layer and pixels of the display panel (that is, the solar energy conversion layer can operate normally). Therefore, while the battery life of the electronic product using the display panel of the embodiments of the present disclosure can be prolonged, the optical properties of the display panel are maintained. That is, the display area of the display panel has a uniform display effect. In addition, the display panel of the embodiments of the present disclosure improves the structural height difference by optimizing the layout design (that is, the sealant layer has the same/similar width and height in the first border area, the second border area, the third border area and the fourth border area) without increasing the number of process steps.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a top view of a display panel according to an embodiment of the present disclosure;

FIG. 2 is a schematic cross-sectional view of an embodiment of the display panel in FIG. 1 along section line AA’;

FIG. 3 is a schematic cross-sectional view of an embodiment of the display panel in FIG. 1 along section line BB’;

FIG. 4 is a top view of the optical substrate of FIGS. 2 and 3 prepared to the first organic layer;

FIG. 5 is a schematic cross-sectional view of an embodiment of the optical substrate in FIG. 4 along section line CC’;

FIG. 6 is a top view of the optical substrate of FIGS. 2 and 3 prepared to the electrode conductive layer;

FIG. 7 is a schematic cross-sectional view of an embodiment of the optical substrate in FIG. 6 along section line DD’; and

FIG. 8 is a top view of the optical substrate of FIGS. 2 and 3 marked with a configuration range of the sealant layer.

### DETAILED DESCRIPTION OF THE EMBODIMENTS

The embodiments of the present disclosure will be described below in conjunction with the relevant drawings. In the figures, the same reference numbers refer to the same or similar components or method flows.

The term “and/or” in the present disclosure describes an association relationship of associated objects, indicating that three relationships may exist. For example, A and/or B may indicate three situations: the existence of A alone, the existence of both A and B, and the existence of B alone.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It should be understood that the terms “lower”, “below”, “upper”, and “above” are used to describe relationship between one element and another (or some other) elements as shown in the drawings. These terms have the relative conceptual meanings and are used to refer to the directions indicated in the drawings.

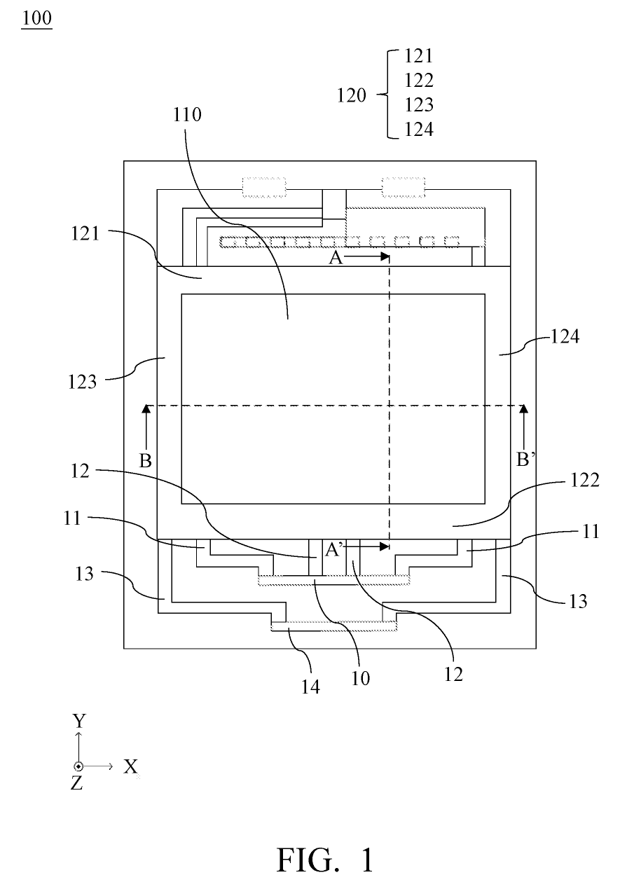

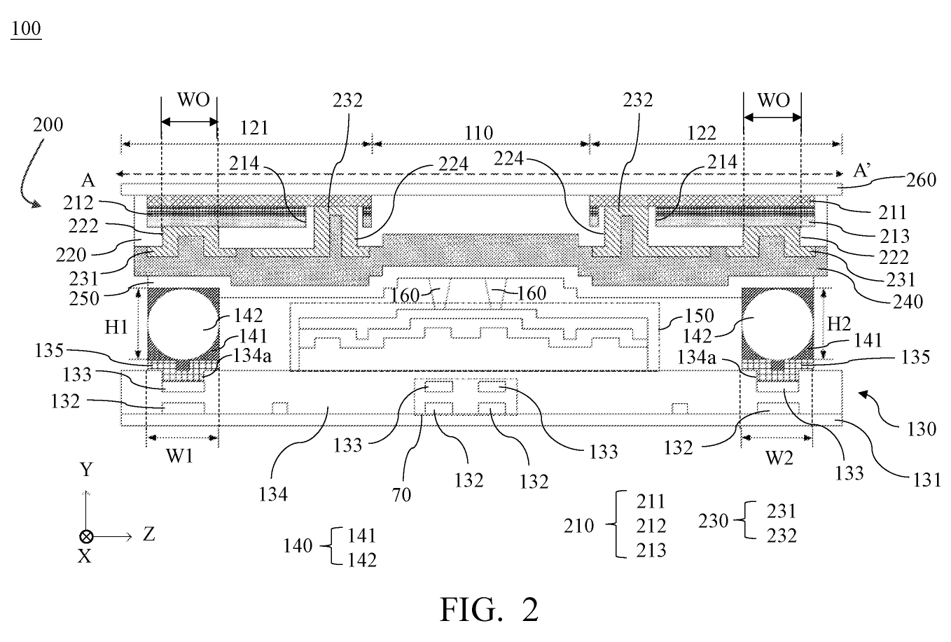

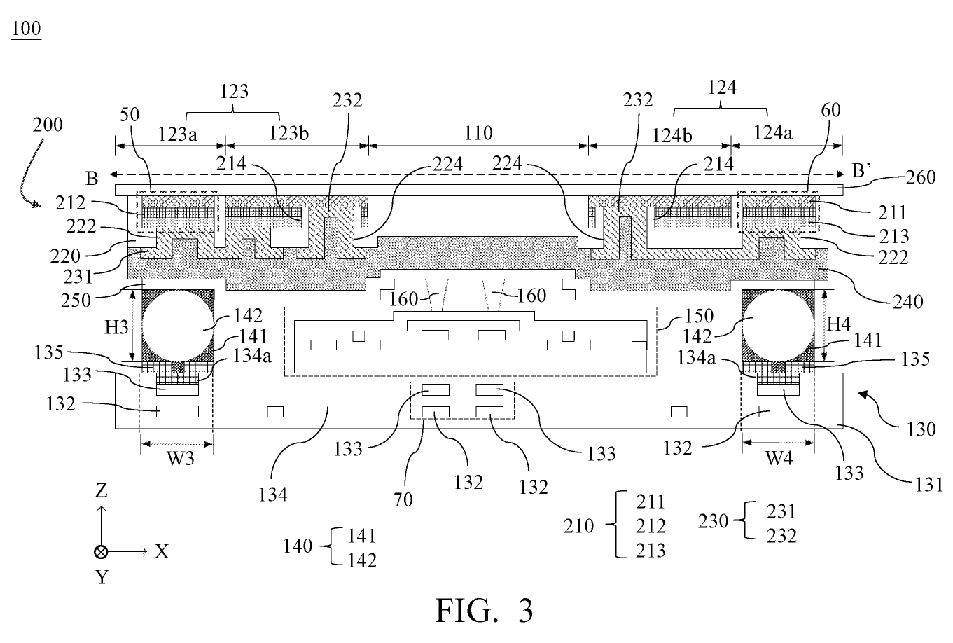

Please refer to FIGS. 1 to 3. FIG. 1 is a top view of a display panel according to an embodiment of the present disclosure, FIG. 2 is a schematic cross-sectional view of an embodiment of the display panel in FIG. 1 along section line AA’, and FIG. 3 is a schematic cross-sectional view of an embodiment of the display panel in FIG. 1 along section line BB’. As shown in FIGS. 1 to 3, a display panel 100 may be defined as a display area 110 and a non-display area 120 surrounding the display area 110. The display area 110 is configured to display a display screen. The non-display area 120 comprises a first border area 121 and a second border area 122 disposed opposite to each other along a first direction (i.e., an X-axis direction) and a third border area 123 and a fourth border area 124 disposed opposite to each other along a second direction (i.e., a Y-axis direction). The first direction is perpendicular to the second direction. The non-display area 120 may be used as a routing region for electronic components of the display panel 100. In addition, the third border area 123 may comprise a routing region 123a and a photoelectric conversion region 123b disposed between the routing region 123a and the display area 110, and the fourth border area 124 may comprise a routing region 124a and a photoelectric conversion region 124b disposed between the routing region 124a and the display area 110.

Please refer to FIGS. 2 and 3. The display panel 100 comprises an array substrate 130, a sealant layer 140 and an optical substrate 200, and the array substrate 130, the sealant layer 140 and the optical substrate 200 are stacked with each other along a third direction (i.e., a Z-axis direction, wherein the Z-axis direction is perpendicular to the X-axis direction and the Y-axis direction). In addition, the display panel 100 may further comprise a display medium (e.g., liquid crystal) (not drawn) disposed on the array substrate 130, surrounded by the sealant layer 140 and covered by the optical substrate 200, and the present disclosure is not limited thereto.

The array substrate 130 may comprise a first substrate 131, a gate layer 132, a source/drain layer 133, a passivation layer 134, and an electrode layer 135. The first substrate 131 may be a rigid substrate, such as a glass substrate, a quartz substrate, and a silicon substrate, or may be a flexible substrate, such as a polymer substrate and a plastic substrate. The material of the passivation layer 134 may comprise, but is not limited to, one of silicon oxide, silicon nitride, or silicon oxynitride, or any combination thereof. The gate layer 132 and the source/drain layer 133 are disposed on the first substrate 131. The gate layer 132 and the source/drain layer 133 are used to electrically connect to an external circuit through a wiring 11 and a wiring 12. For example, the gate layer 132 is electrically connected to a driving circuit 10 of the display panel 100 through the wiring 11 (as shown in FIG. 1 ) to provide the gate driving signals from the driving circuit 10 to the corresponding array transistors; and the source/drain layer 133 is electrically connected to the driving circuit 10 through the wiring 12 (as shown in FIG. 1 ) to provide the source driving signals from the driving circuit 10 to the corresponding array transistors. The gate layer 132 and the source/drain layer 133 may be metal thin film layers, and the materials of the gate layer 132 and the source/drain layer 133 may comprise, but are not limited to, aluminum, copper, gold, chromium, tantalum, titanium, manganese, nickel, molybdenum, niobium, neodymium, silver or a combination thereof.

The passivation layer 134 is disposed on the first substrate 131 and covers the gate layer 132 and the source/drain layer 133 to isolate the gate layer 132 from the source/drain layer 133 to avoid unexpected electrical connection paths. The passivation layer 134 is further provided with an annular groove 134a, and the annular groove 134a is configured to expose the source/drain layer 133 located in the non-display area 120. The electrode layer 135 is located in the non-display area 120. The electrode layer 135 is disposed on a portion of the passivation layer 134 and the annular groove 134a to electrically connect to the source/drain layer 133 exposed by the annular groove 134a. The electrode layer 135 may be a transparent conductive film, and the material of the electrode layer 135 may comprise, but is not limited to, indium tin oxide (ITO) or indium zinc oxide (IZO).

The sealant layer 140 is disposed on the array substrate 130 and corresponds to the first border area 121, the second border area 122, the routing region 123a of the third border area 123 and the routing region 124a of the fourth border area 124 (that is, the sealant layer 140 is disposed corresponding to the non-display area 120), and the sealant layer 140 is electrically connected to the array substrate 130.

The optical substrate 200 is disposed on the sealant layer 140 and comprises a solar energy conversion layer 210, a first organic layer 220, an electrode conductive layer 230, a second organic layer 240 and a common electrode layer 250, wherein the solar energy conversion layer 210, the first organic layer 220, the electrode conductive layer 230, the second organic layer 240 and the common electrode layer 250 are stacked with each other along the third direction (i.e., the Z-axis direction, wherein the Z-axis direction being perpendicular to the X-axis direction and the Y-axis direction). In addition, the optical substrate 200 may further comprise a second substrate 260, which covers the solar energy conversion layer 210 to protect the solar energy conversion layer 210. The second substrate 260 may be a transparent substrate, such as glass and plastic, but is not limited thereto.

The solar energy conversion layer 210 is disposed in the non-display area 120. The solar energy conversion layer 210 may comprise a positive electrode layer 211, a photoelectric conversion layer 212, and a negative electrode layer 213 sequentially stacked on the second substrate 260. The solar energy conversion layer 210 located in the first border area 121, the second border area 122, the photoelectric conversion region 123b of the third border area 123 and the photoelectric conversion region 124b of the fourth border area 124 may be defined as a solar cell unit having a photoelectric conversion function. The solar energy conversion layer 210 located in the routing region 123a of the third border area 123 does not have the photoelectric conversion function and only serves as a negative electrode wiring layer 50. The solar energy conversion layer 210 located in the routing region 124a of the fourth border area 124 does not have the photoelectric conversion function and only serves as a positive electrode wiring layer 60. The negative electrode wiring layer 50 and the positive electrode wiring layer 60 are photoelectric transmission wiring layers. The positive electrode layer 211 may be a transparent conductive layer, and the material of the positive electrode layer 211 may be, but not limited to, aluminum-doped zinc oxide (AZO). The photoelectric conversion layer 212 may be a PIN semiconductor stacked structure having a P-type semiconductor layer, an intrinsic layer, and an N-type semiconductor layer, and the material of the photoelectric conversion layer 212 may comprise, but is not limited to, amorphous silicon, polycrystalline silicon, cadmium telluride, copper indium gallium selenide, gallium arsenide, or polymer. The negative electrode layer 213 may be a metal thin film layer, and the material of the negative electrode layer 213 may comprise, but is not limited to, aluminum, silver, or chromium.

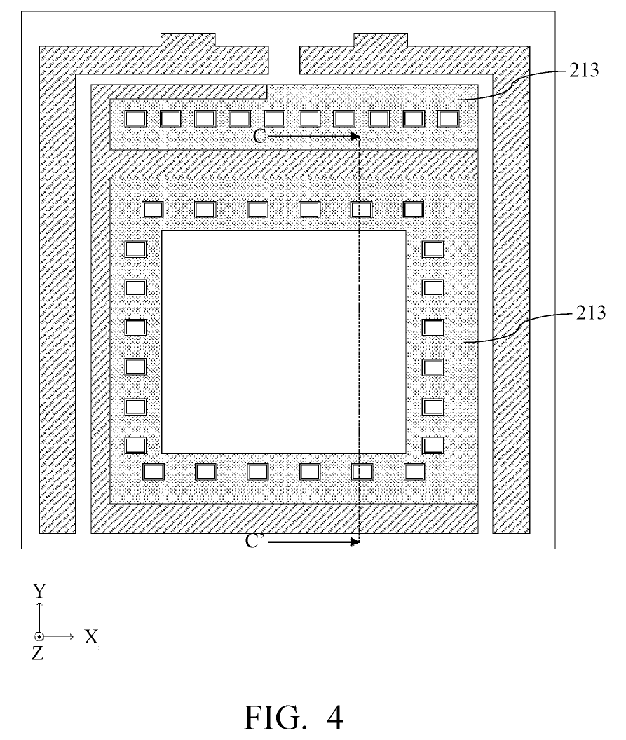

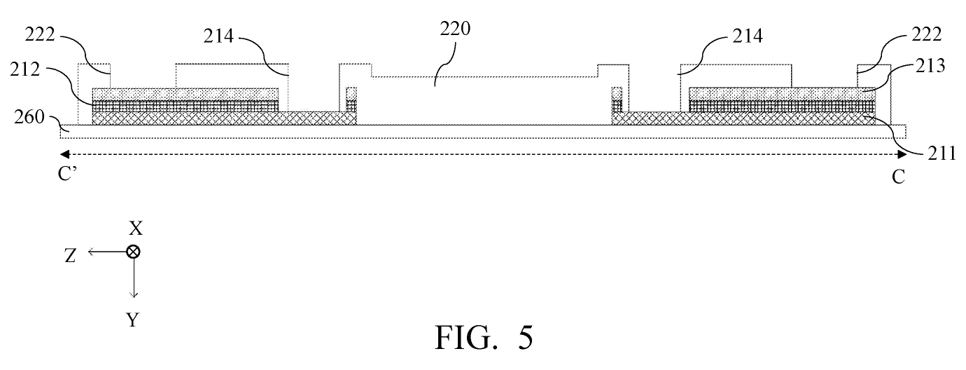

The first organic layer 220 covers the solar energy conversion layer 210 and is provided with an annular opening 222. The annular opening 222 is disposed corresponding to the sealant layer 140, and the annular opening 222 exposes a portion of the solar energy conversion layer 210 located in the non-display area 120. Specifically, the annular opening 222 penetrates the first organic layer 220, and the annular opening 222 exposes the negative electrode layer 213 of a portion of the solar energy conversion layer 210 located in the first border area 121 and the second border area 122, exposes a portion of the negative electrode wiring layer 50 located in the routing region 123a of the third border area 123, and exposes a portion of the positive electrode wiring layer 60 located in the routing region 124a of the fourth border area 124. Therefore, the first organic layer 220 corresponding to the sealant layer 140 has the same structural design in the first border area 121, the second border area 122, the third border area 123 and the fourth border area 124 (as shown in FIGS. 4 and 5, wherein FIG. 4 is a top view of the optical substrate of FIGS. 2 and 3 prepared to the first organic layer, and FIG. 5 is a schematic cross-sectional view of an embodiment of the optical substrate in FIG. 4 along section line CC’). It should be noted that the optical substrate 200 of the display panel 100 is independently manufactured and then disposed on the sealant layer 140, and the preparation of the optical substrate 200 is to stack the solar energy conversion layer 210, the first organic layer 220, the electrode conductive layer 230, the second organic layer 240 and the common electrode layer 250 in sequence on the second substrate 260. In one embodiment, an outer edge of the first organic layer 220 is more protrusive than an outer edge of the sealant layer 140, and a distance between the outer edge of the first organic layer 220 and the outer edge of the sealant layer 140 along the Z-axis direction may be 10 microns (μm) to 30μm. In addition, the first organic layer 220 covers the solar energy conversion layer 210 at an outer edge of the display panel 100, which can avoid the reliability problem caused by the exposure of the solar energy conversion layer 210.

The electrode conductive layer 230 is disposed on the first organic layer 220 and comprises a negative electrode conductive layer 231 and a positive electrode conductive layer 232. The negative electrode conductive layer 231 is electrically connected to the solar energy conversion layer 210 located in the first border area 121, the second border area 122 and the third border area 123 and exposed by the first organic layer 220. The positive electrode conductive layer 232 is electrically connected to the solar energy conversion layer 210 located in the fourth border area 124 and exposed by the first organic layer 220. Specifically, the negative electrode conductive layer 231 is disposed on a portion of the first organic layer 220 and the annular opening 222 in the first border area 121, the second border area 122, and the third border area 123 to be electrically connected to the negative electrode layer 213 and the negative electrode wiring layer 50 exposed by the first organic layer 220. The positive electrode conductive layer 232 is disposed on a portion of the first organic layer 220 and the annular opening 222 in the fourth border area 124 to be electrically connected to the positive electrode wiring layer 60 exposed by the first organic layer 220. Therefore, through the above-mentioned disposition of the negative electrode conductive layer 231 and the positive electrode conductive layer 232, the first border area 121, the second border area 122, the third border area 123, and the fourth border area 124 corresponding to sealant layer 140 may have the same structural design. The negative electrode conductive layer 231 and the positive electrode conductive layer 232 may be metal conductive layers, and the materials of the negative electrode layer 213 and the positive electrode conductive layer 232 may comprise, but are not limited to, aluminum, copper, gold, chromium, tantalum, titanium, manganese, nickel, molybdenum, niobium, neodymium, silver or a combination thereof.

The second organic layer 240 is disposed on the electrode conductive layer 230. Specifically, the second organic layer 240 covers the electrode conductive layer 230 and the first organic layer 220 not covered by the electrode conductive layer 230, so as to electrically insulate the solar energy conversion layer 210, so that the electrical properties of the solar energy conversion layer 210 are maintained on the color filter layer side. The common electrode layer 250 is disposed on the second organic layer 240 and is electrically connected to the sealant layer 140. The common electrode layer 250 may be electrically connected to an external circuit through a wiring 13. For example, the common electrode layer 250 may be electrically connected to the flexible circuit board 14 through the wiring 13 (as shown in FIG. 1).

In this embodiment, by the design of the first organic layer 220, the negative electrode conductive layer 231 and the positive electrode conductive layer 232, the sealant layer 140 of the display panel 100 has the same/similar width and height in the first border area 121, the second border area 122, the third border area 123 and the fourth border area 124. The second organic layer 240 is designed to electrically isolate the solar energy conversion layer 210 from the common electrode layer 250, so that the solar energy conversion layer 210 can operate normally. Therefore, while the battery life of the electronic product using the display panel 100 can be prolonged, the optical properties of the display panel 100 are maintained. That is, the display area 110 of the display panel 100 has a uniform display effect.

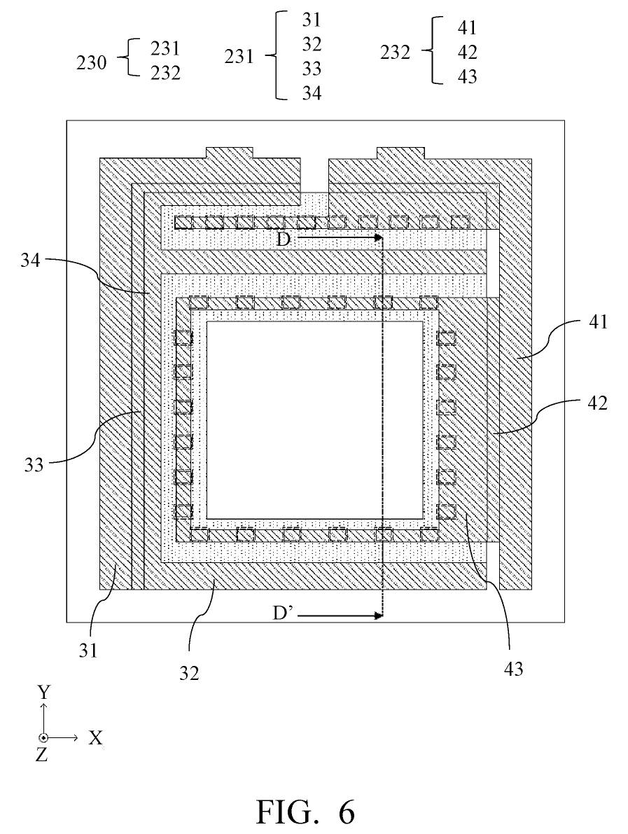

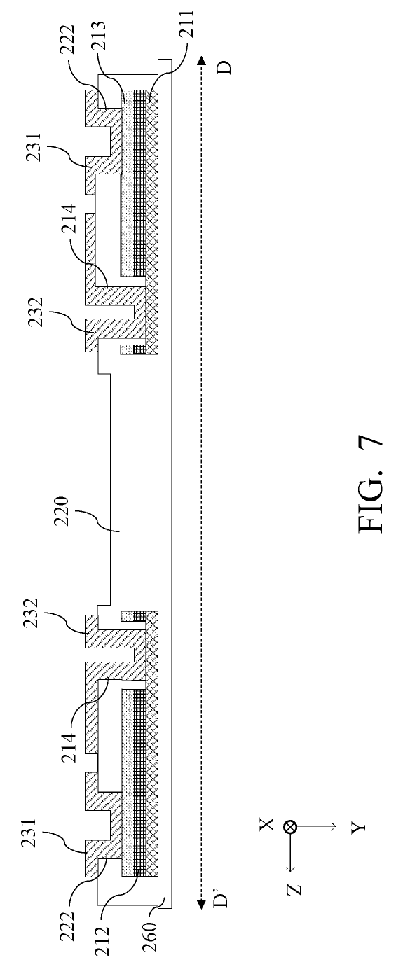

In one embodiment, the negative electrode conductive layer 231 located in the first border area 121, the second border area 122 and the third border area 123 has a U-shaped outline in a top view (as shown in FIGS. 6 and 7, wherein FIG. 6 is a top view of the optical substrate of FIGS. 2 and 3 prepared to the electrode conductive layer, and FIG. 7 is a schematic cross-sectional view of an embodiment of the optical substrate in FIG. 6 along section line DD’). In addition, the negative electrode conductive layer 231 may be divided into a first negative bus line 31, a second negative bus line 32, a climbing area 33 and a conversion area 34.

In one embodiment, please refer to FIGS. 2 , 3 and 6, the solar energy conversion layer 210 is provided with an annular groove 214 close to the display area 110, and the annular groove 214 surrounds the display area 110 and exposes the positive electrode layer 211 of the solar energy conversion layer 210. The first organic layer 220 is further provided with an annular opening 224 penetrating the first organic layer 220 and corresponding to the annular groove 214. The positive electrode conductive layer 232 may also be disposed on the annular groove 214, the annular opening 224 and a portion of the first organic layer 220 located in the fourth border area 124 to be electrically connected to the positive electrode layer 211 exposed by the annular groove 214. Since the positive electrode conductive layer 232 may be disposed on the annular groove 214 and the annular opening 224, a portion of the positive electrode conductive layer 232 has a hollow square shape in a top view (as shown in FIG. 6). Specifically, the positive electrode conductive layer 232 may be divided into a positive bus line 41, a climbing area 42 and a conversion area 43, and the conversion area 43 has the hollow square shape in the top view.

In one embodiment, a height H1 of the sealant layer 140 located in the first border area 121, a height H2 of the sealant layer 140 located in the second border area 122, a height H3 of the sealant layer 140 located in the third border area 123 and a height H4 of the sealant layer 140 located in the fourth border area 124 may be the same (as shown in FIGS. 2 and 3).

In one embodiment, a width W1 of the sealant layer 140 located in the first border area 121, a width W2 of the sealant layer 140 located in the second border area 122, a width W3 of the sealant layer 140 located in the third border area 123, and a width W4 of the sealant layer 140 located in the fourth border area 124 may be the same (as shown in FIGS. 2 and 3).

In one embodiment, the sealant layer 140 may comprise conductive particles 142, and the conductive particles 142 are electrically connected to the common electrode layer 250 and the electrode layer 135 of the array substrate 130 (as shown in FIGS. 2 and 3). Specifically, the sealant layer 140 comprises a sealant 141 and the conductive particles 142 disposed in the sealant 141, and the sealant 141 is attached to the common electrode layer 250 and the electrode layer 135, so that the conductive particles 142 abut against the common electrode layer 250 and the electrode layer 135. The heights of the sealant layer 140 in different border areas can be used to determine the particle size of conductive particles 142. When the heights of the sealant layer 140 in different border areas are different, the particle size of the conductive particle 142 corresponding to the lowest height of the sealant layer 140 in different border areas may be selected. However, there is a problem of insufficient supporting force. The heights of sealant layer 140 in different border areas of the present disclosure are the same/similar, so the conductive particles 142 may abut against the common electrode layer 250 and the electrode layer 135, and there is no problem of insufficient supporting force.

In one embodiment, the width W1, the width W2, the width W3 and the width W4 are the same, and a width of the sealant layer 140 (i.e., the width W1, the width W2, the width W3 or the width W4) may be, but is not limited to, 600μm to 1200μm.

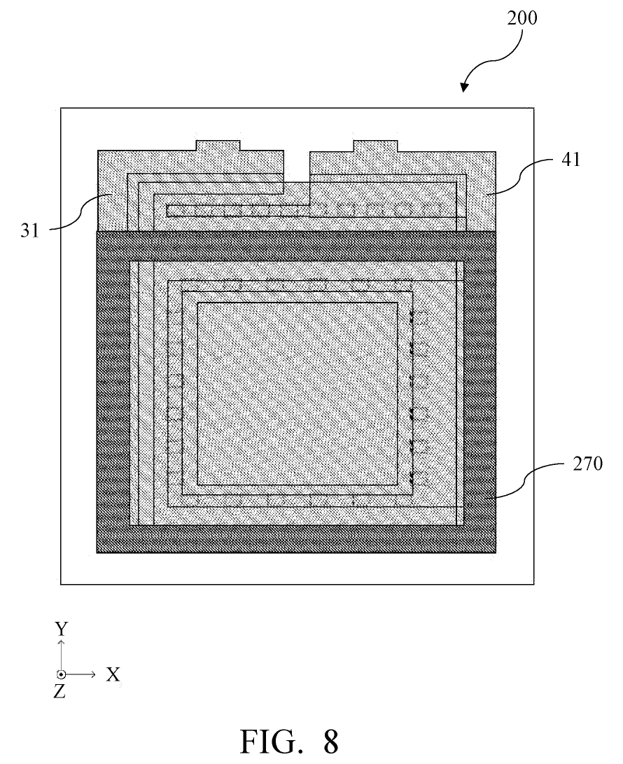

In one embodiment, a vertical projection of the annular opening 222 on the array substrate 130 overlaps with a vertical projection of the sealant layer 140 on the array substrate 130, and a width WO of the annular opening 222 is smaller than the width of the sealant layer 140 (i.e., the width W1, the width W2, the width W3 or the width W4) (as shown in FIGS. 2 , 3 and 8, wherein FIG. 8 is a top view of the optical substrate of FIGS. 2 and 3 marked with a configuration range of the sealant layer, and the configuration range of the sealant layer in FIG. 8 is marked as a component symbol 270). The difference between the width WO of the annular opening 222 and the width of the sealant layer 140 (i.e., the width W1, the width W2, the width W3 or the width W4) is about 25μm to 100μm.

In one embodiment, the display panel 100 may further comprise a reflective layer 150, which is disposed between the optical substrate 200 and the array substrate 130 and is located on the array substrate 130 (as shown in FIGS. 2 and 3). That is, the display panel 100 may be, but is not limited to, a reflective display panel or a semi-transmissive and semi-reflective display panel.

In one embodiment, the display panel 100 may further comprise at least one photo spacer 160, which is disposed between the reflective layer 150 and the optical substrate 200 (as shown in FIGS. 2 and 3).

In one embodiment, the array substrate 130 is provided with a storage capacitor 70, which is disposed corresponding to the reflective layer 150 (that is, the storage capacitor 70 is located below the reflective layer 150), and the storage capacitor 70 is composed of the gate layer 132, the passivation layer 134, and the source/drain layer 133. In another embodiment, there is only the passivation layer 134 of the array substrate 130 below the reflective layer 150 (as shown in FIG. 2 and FIG. 3).

In summary, in the display panel of the embodiments of the present disclosure, by the annular opening in the first organic layer corresponding to the sealant layer, the electrical connection between the negative conductive layer and the solar energy conversion layer located in the first border area, the second border area and the third border area and exposed by the first organic layer, and the electrical connection between the positive conductive layer and the solar energy conversion layer located in the fourth border area and exposed by the first organic layer, the sealant layer of the display panel has the same/similar width and height in the first border area, the second border area, the third border area and the fourth border area. The second organic layer is configured to electrically isolate the solar energy conversion layer with photoelectric conversion capability from the common electrode layer, so that it can avoid affecting the electrical properties of the solar energy conversion layer and the pixels of the display panel (that is, the solar energy conversion layer can operate normally). Therefore, while the battery life of the electronic product using the display panel of the embodiments of the present disclosure can be prolonged, the optical properties of the display panel are maintained. That is, the display area of the display panel has a uniform display effect. In addition, the display panel of the embodiments of the present disclosure improves the structural height difference by optimizing the layout design (that is, the sealant layer has the same/similar width and height in the first border area, the second border area, the third border area and the fourth border area) without increasing the number of process steps.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A display panel having a display area and a non-display area surrounding the display area, the non-display area comprising a first border area and a second border area disposed opposite to each other along a first direction and a third border area and a fourth border area disposed opposite to each other along a second direction, the first direction being perpendicular to the second direction, the display panel comprising:
an array substrate;
a sealant layer disposed on the array substrate and corresponding to the non-display area, wherein the sealant layer is electrically connected to the array substrate; and
an optical substrate disposed on the sealant layer and comprising:
a solar energy conversion layer disposed in the non-display area;
a first organic layer configured to cover the solar energy conversion layer and provided with an annular opening, wherein the annular opening is disposed corresponding to the sealant layer, the annular opening exposes a portion of the solar energy conversion layer located in the non-display area;
an electrode conductive layer disposed on the first organic layer and comprising a negative electrode conductive layer and a positive electrode conductive layer, wherein the negative electrode conductive layer is electrically connected to the solar energy conversion layer located in the first border area, the second border area and the third border area and exposed by the first organic layer, and the positive electrode conductive layer is electrically connected to the solar energy conversion layer located in the fourth border area and exposed by the first organic layer;
a second organic layer disposed on the electrode conductive layer; and
a common electrode layer disposed on the second organic layer and electrically connected to the sealant layer.

2. The display panel according to claim 1, wherein the solar energy conversion layer is provided with an annular groove close to the display area, the annular groove surrounds the display area and exposes a positive electrode layer of the solar energy conversion layer; the first organic layer is further provided with another annular opening penetrating the first organic layer and corresponding to the annular groove; the positive electrode conductive layer is also disposed on the annular groove, the another annular opening and a portion of the first organic layer located in the fourth border area to be electrically connected to the positive electrode layer exposed by the annular groove.

3. The display panel according to claim 1, wherein the sealant layer comprises conductive particles, and the conductive particles are electrically connected to the common electrode layer and an electrode layer of the array substrate.

4. The display panel according to claim 3, wherein the second organic layer covers the electrode conductive layer and the first organic layer not covered by the electrode conductive layer.

5. The display panel according to claim 3, wherein each of the third border area and the fourth border area comprises a routing region and a photoelectric conversion region disposed between the routing region and the display area, and the sealant layer is disposed corresponding to the first border area, the second border area, the routing region of the third border area, and the routing region of the fourth border area.

6. The display panel according to claim 1, further comprising a reflective layer, wherein the reflective layer is disposed between the optical substrate and the array substrate and located on the array substrate.

7. The display panel according to claim 6, wherein the second organic layer covers the electrode conductive layer and the first organic layer not covered by the electrode conductive layer.

8. The display panel according to claim 6, wherein each of the third border area and the fourth border area comprises a routing region and a photoelectric conversion region disposed between the routing region and the display area, and the sealant layer is disposed corresponding to the first border area, the second border area, the routing region of the third border area, and the routing region of the fourth border area.

9. The display panel according to claim 1, wherein the negative electrode conductive layer located in the first border area, the second border area and the third border area has a U-shaped outline in a top view.

10. The display panel according to claim 1, wherein a height of the sealant layer located in the first border area, a height of the sealant layer located in the second border area, a height of the sealant layer located in the third border area and a height of the sealant layer located in the fourth border area are the same.

11. The display panel according to claim 10, wherein the second organic layer covers the electrode conductive layer and the first organic layer not covered by the electrode conductive layer.

12. The display panel according to claim 10, wherein each of the third border area and the fourth border area comprises a routing region and a photoelectric conversion region disposed between the routing region and the display area, and the sealant layer is disposed corresponding to the first border area, the second border area, the routing region of the third border area, and the routing region of the fourth border area.

13. The display panel according to claim 1, wherein a width of the sealant layer located in the first border area, a width of the sealant layer located in the second border area, a width of the sealant layer located in the third border area and a width of the sealant layer located in the fourth border area are the same.

14. The display panel according to claim 13, wherein each of the third border area and the fourth border area comprises a routing region and a photoelectric conversion region disposed between the routing region and the display area, and the sealant layer is disposed corresponding to the first border area, the second border area, the routing region of the third border area, and the routing region of the fourth border area.

15. The display panel according to claim 13, wherein a width of the sealant layer is 600 microns (μm) to 1200μm.

16. The display panel according to claim 13, wherein a vertical projection of the annular opening on the array substrate overlaps a vertical projection of the sealant layer on the array substrate, and a width of the annular opening is smaller than a width of the sealant layer.

17. The display panel according to claim 1, wherein the second organic layer covers the electrode conductive layer and the first organic layer not covered by the electrode conductive layer.

18. The display panel according to claim 1, wherein each of the third border area and the fourth border area comprises a routing region and a photoelectric conversion region disposed between the routing region and the display area, and the sealant layer is disposed corresponding to the first border area, the second border area, the routing region of the third border area, and the routing region of the fourth border area.

19. The display panel according to claim 18, wherein the solar energy conversion layer in the routing region of the third border area serves as a negative electrode wiring layer, and the solar energy conversion layer in the routing region of the fourth border area serves as a positive electrode wiring layer; the annular opening exposes a negative electrode layer of a portion of the solar energy conversion layer located in the first border area and the second border area, exposes a portion of the negative electrode wiring layer located in the routing region of the third border area, and exposes a portion of the positive electrode wiring layer located in the routing region of the fourth border area.

20. The display panel according to claim 19, wherein the negative electrode conductive layer is disposed on the annular opening and a portion of the first organic layer, which correspond to the first border area, the second border area, and the third border area, so as to be electrically connected to the negative electrode layer and the negative electrode wiring layer exposed by the first organic layer; and the positive electrode conductive layer is disposed on the annular opening and a portion of the first organic layer, which correspond to the fourth border area, so as to be electrically connected to the positive electrode wiring layer exposed by the first organic layer.
